(19) United States
(12) Patent Application Publication
(10) Pub. No.: US 2017/0067564 A1
(43) Pub. Date: Mar. 9, 2017

(54) VALVE AND SEMICONDUCTOR MANUFACTURING EQUIPMENT

(71) Applicant: Kabushiki Kaisha Toshiba, Tokyo (JP)

(72) Inventors: Eiichi Nagumo, Nonoichi Ishikawa (JP); Hiroshi Sanda, Kanazawa Ishikawa (JP); Makoto Saito, Nomi Ishikawa (JP)

(21) Appl. No.: 15/017,815

(22) Filed: Feb. 8, 2016

(30) Foreign Application Priority Data
Sep. 7, 2015 (JP) 2015-175673

(51) Int. Cl. F16K 3/02; C23C 16/44; H01J 37/32; F16K 3/10; H01L 21/67

(52) U.S. Cl. CPC F16K 3/0209; F16K 3/029; F16K 3/10; H01L 21/67069; H01J 37/32009; C23C 16/44; H01J 2237/334

(57) ABSTRACT

A valve includes a housing which includes a first opening part connectable to a first pipe and a second opening part connectable to a second pipe. A first valve is provided in the housing and is capable of being inserted into or removed from between the first opening part and the second opening part. The first valve includes an outer edge located outside an outer edge of the first or second opening part. The first valve has a third opening part smaller than the first and second opening parts. A second valve is provided in the housing, and is capable of being inserted into or removed from between the first opening part and the second opening part. The second valve includes an outer edge located outside an outer edge of the third opening part. The second valve is capable of closing at least a part of the third opening part.

### CROSS REFERENCE TO RELATED APPLICATIONS

This application is based upon and claims the benefit of priority from the prior Japanese Patent Application 2015-175673, filed on Sep. 7, 2015, the entire contents of which are incorporated herein by reference.

### FIELD

The embodiments of the present invention relate to a valve and a semiconductor manufacturing equipment.

### BACKGROUND

A semiconductor manufacturing equipment such as an etching system or a Chemical Vapor Deposition (CVD) system keeps the Inside of a chamber in a vacuumed state while processing a semiconductor wafer. To control the pressure in the chamber, a pressure control valve is sometimes provided between the chamber and a vacuum pump. The pressure control valve has a valve element adapted to the opening diameter of a pipe and opens or closes an opening part of the pipe with the valve element to control the pressure in the chamber. However, it is difficult to finely adjust the pressure in the chamber with a conventional pressure control valve.

### BRIEF DESCRIPTION OF THE DRAWINGS

FIG. 1 is a schematic diagram showing an example of a configuration of a dry etching system 1 according to a first embodiment;

FIG. 2 is a cross-sectional view showing an example of a configuration of the pressure control valve 40 according to the first embodiment;

FIG. 3 is a plan view showing an example of configurations of the first and second valve elements 41 and 42;

FIG. 4 shows a state where the second valve element 42 is moved with respect to the first valve element 41 overlapped with the first or second opening part OP1 or OP2;

FIG. 5 is a plan view showing an example of a configuration of the pressure control valve 40 according to a second embodiment;

FIG. 6 shows a state where the second valve element 42 is moved with respect to the first valve element 41 overlapped with the first or second opening part OP1 or OP2;

FIG. 7 is a plan view showing an example of a configuration of the pressure control valve 40 according to a modification of the first embodiment; and

FIG. 8 is a plan view showing a motion of the cutout CO2 with respect to the third opening part OP3.

### DETAILED DESCRIPTION

Embodiments will now be explained with reference to the accompanying drawings. The present invention is not limited to the embodiments.

A valve according to the present embodiment includes a housing. The housing includes a first opening part connectable to a first pipe and a second opening part connectable to a second pipe, and is capable of connecting the first pipe and the second pipe. A first valve element is provided in the housing and is capable of being inserted into or removed from between the first opening part and the second opening part. The first valve element includes an outer edge located outside an outer edge of the first or second opening part. The first valve element has a third opening part smaller than the first and second opening parts. A second valve element is provided in the housing, and is capable of being inserted into or removed from between the first opening part and the second opening part. The second valve element includes an outer edge located outside an outer edge of the third opening part. The second valve element is capable of closing at least a part of the third opening part.

### First Embodiment

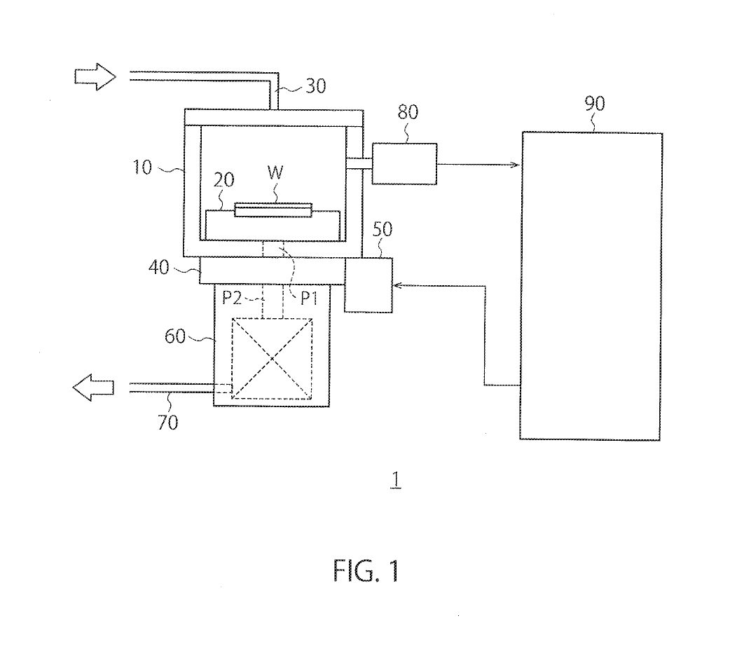

FIG. 1 is a schematic diagram showing an example of a configuration of a dry etching system 1 (hereinafter, also “etching system 1”) according to a first embodiment. The etching system 1 includes a chamber 10, a stage 20, a gas delivery line 30, a pressure control valve 40, a valve driver 50, a vacuum pump (Turbo Molecular Pump (TMP) or Turbo Pump) 60, an exhaust line 70, a pressure gauge 80, and a controller 90. The etching system 1 is, for example, a plasma etching system that performs RIE (Reactive Ion Etching) and the like.

The first embodiment is applicable to any semiconductor manufacturing device (a CVD system, for example) that requires a vacuumed environment as well as the etching system.

The chamber 10 is used to process a semiconductor wafer (hereinafter, also simply “wafer”) W mounted on the stage 20 or a material film on the wafer W with an etching gas supplied from the gas delivery line 30. The inside of the chamber 10 is vacuumed when the wafer W is subjected to etching processing.

The stage 20 is provided in the chamber 10 and can have the wafer W as a processing target mounted thereon. The stage 20 is used as one of electrodes during plasma etching. The stage 20 is configured to be rotatable in a state having the wafer W mounted thereon.

The gas delivery line 30 supplies the etching gas into the chamber 10. The etching gas is changed to plasma by application of a radio-frequency power (voltage), with an electromagnetic wave, or the like in the chamber 10 and the wafer W or the material film thereon is etched by the etching gas changed to plasma.

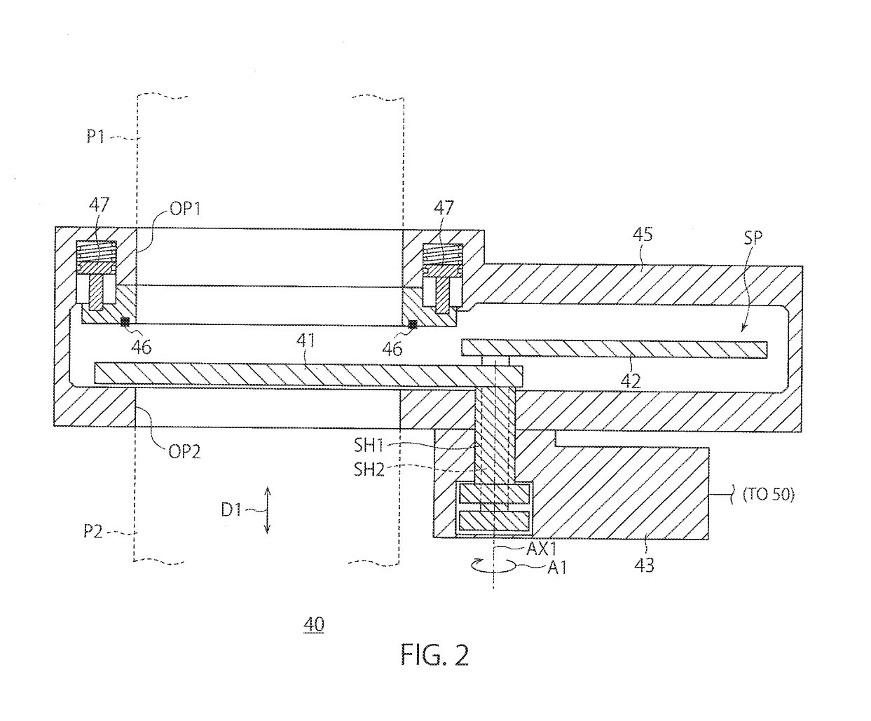

The pressure control valve 40 is provided in a pipe connecting the chamber 10 and the vacuum pump 60 and can open or close between the chamber 10 and the vacuum pump 60. For example, the pressure control value 40 is interposed between a first pipe P1 connected to the chamber 10 and a second pipe P2 connected to the vacuum pump 60 and opens or closes (blocks) between the first pipe P1 and the second pipe P2. When closing between the first pipe P1 and the second pipe P2, the pressure control valve 40 airtightly blocks between the chamber 10 and the vacuum pump 60. Accordingly, the pressure control valve 40 airtightly blocks the chamber 10 from the vacuum pump 60 to seal the inside of the chamber 10. The pressure control valve 40 also changes the opening degrees of the pipes to regulate (control) a gas conductance between the first pipe P1 and the second pipe P2, thereby controlling the pressure in the chamber 10. A configuration of the pressure control valve 40 is explained later with reference to FIG. 2.

The valve driver 50 drives the pressure control valve 40 under control of the controller 90. Upon reception of driving of the valve driver 50, the pressure control valve 40 can open or close between the first pipe P1 and the second pipe P2. Upon reception of driving of the valve driver 50, the pressure control valve 40 can also control the conductance between the first pipe P1 and the second pipe P2.

The vacuum pump 60 discharges the gas in the chamber 10 to the exhaust line 70 via the pipes P1 and P2 and the pressure control valve 40 to vacuum the inside of the chamber 10. The vacuum pump 60 thereby brings the inside of the chamber 10 to a vacuumed state. The vacuum pump 60 also transmits unwanted gases generated by etching to the exhaust line 70. The exhaust line 70 is connected to the vacuum pump 60 and discharges the gases from the vacuum pump 60 to outside of the etching system 1.

The pressure gauge 80 measures the pressure in the chamber 10 and outputs a measurement value of the pressure to the controller 90. The controller 90 controls the valve driver 50 based on the pressure measurement value output from the pressure gauge 80. The pressure control valve 40 is driven by the valve driver 50 to control the pressure in the chamber 10. The controller 90 thus feeds back an actual pressure value in the chamber 10 and maintains the inside of the chamber 10 at a desired pressure.

The etching system 1 having the configuration described above can process the wafer W on the stage 20 or the material film on the wafer W using the etching gas.

FIG. 2 is a cross-sectional view showing an example of a configuration of the pressure control valve 40 according to the first embodiment.

The pressure control valve 40 includes a housing 45, a first valve element 41, a second valve element 42, a transfer mechanism 43, and a pressing part 46. As described above, the pressure control valve 40 is interposed between the first pipe P1 connected to the chamber 10 and the second pipe P2 connected to the vacuum pump 60 and can open/close between the first pipe P1 and the second pipe P2. Accordingly, the vacuum pump 60 can discharge the gases from the chamber 10 via the pressure control valve 40 to depressurize the inside of the chamber 10.

The housing 45 has a first opening part OP1 having one end connectable to the first pipe P1 and a second opening part OP2 having one end connectable to the second pipe P2. Other ends of the first and second opening parts OP1 and OP2 are connected to a space SP provided in the inside of the housing 45 and the first and second opening parts OP1 and OP2 are communicated with each other via the space SP. The first and second valve elements 41 and 42 are provided in the space SP of the housing 45. The space SP is in an airtight state in the housing 45. Accordingly, the housing 45 can connect the first pipe P1 and the second pipe P2 in an airtight state. To prevent corrosion due to the gases from the chamber 10, highly corrosive-resistant metal such as aluminum or stainless steel is used as the housing 45.

The first valve element 41 is provided in the space SP in the housing 45 and is rotatable around an axis AX1 of a first shaft SH1 in the direction of an arrow A1. The first shaft SH1 is driven by the valve driver 50 via the transfer mechanism 43. The first valve element 41 can thereby move rotationally around the axis AX1 in a direction substantially perpendicular to a direction (a direction in which the gases flow) D1 of connection between the first pipe P1 and the second pipe P2. Due to such rotation of the first valve element 41, the first valve element 41 can be inserted into between the first opening part OP1 and the second opening part OP2 or removed therefrom. FIG. 2 shows a state in which the first valve element 41 is inserted into between the first opening part OP1 and the second opening part OP2. Highly corrosive-resistant metal such as aluminum or stainless steel is used as the first valve element 41.

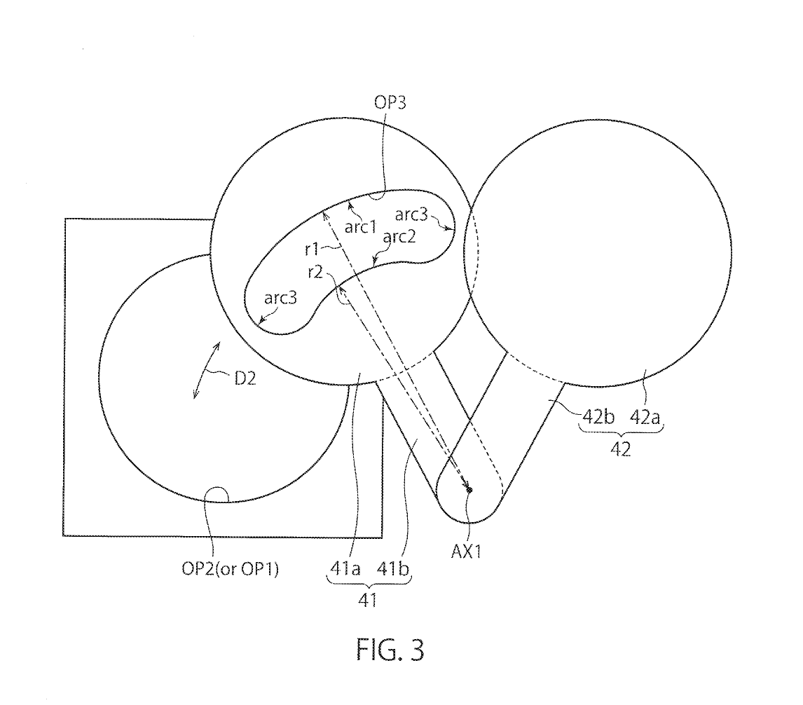

As explained later with reference to FIG. 3, the first valve element 41 has a third opening part OP3 smaller than the second opening part OP2. Accordingly, when the first valve element 41 is inserted into between the first opening part OP1 and the second opening part OP2 to overlap with the second opening part OP2, the first valve element 41 changes the opening area of the second opening part OP2 to the opening area of the third opening part OP3. That is, the first valve element 41 can change the gas conductance between the first pipe P1 and the second pipe P2 in a stepwise manner.

Meanwhile, the second valve element 42 is also provided in the space SP in the housing 45 and is rotatable around an axis AX1 of a second shaft SH2 in the direction of the arrow A1. In the first embodiment, the second shaft SH2 rotates around substantially the same axis (common axis) AX1 as that of the first shaft SH1.

In this case, for example, the second shaft SH2 penetrates the first shaft SH1 and is provided to be rotatable independently of the first shaft SH1. The second shaft SH2 is also driven by the valve driver 50 via the transfer mechanism 43 and can rotate independently of the first shaft SH1. The second valve element 42 can thereby rotate around the axis AX1 in a direction substantially perpendicular to the direction D1 in which the gases flow. Due to such rotation of the second valve element 42, the second valve element 42 can be inserted into between the first opening part OP1 and the second opening part OP2 or removed therefrom similarly to the first valve element 41. FIG. 2 shows a state in which the second valve element 42 is removed from between the first opening part OP1 and the second opening part OP2.

As explained later with reference to FIG. 3, the second valve element 42 has no opening part. Therefore, for example, after the first valve element 41 overlaps with the second opening part OP2, the second valve element 42 can partially close the third opening part OP3. In this case, the second valve element 42 can finely adjust the gas conductance between the first pipe P1 and the second pipe P2.

The rotation axis of the second shaft SH2 can be different from that of the first shaft SH1. That is, the second shaft SH2 can be provided at a position different from that of the first shaft SH1 to rotate around an axis (not shown) different from the rotation axis of the first shaft SH1. However, the second valve element 42 needs to be capable of being inserted into or removed from between the first opening part OP1 and the second opening part OP2 and needs to be configured to be capable of closing the third opening part OP3. Highly corrosive-resistant metal such as aluminum or stainless steel is also used as the second valve element 42.

The transfer mechanism 43 is a mechanism including a gear or the like interposed between the valve driver 50 and the shafts SH1 and SH2 and rotates the shafts SH1 and SH2 upon reception of driving of the valve driver 50.

The pressing part 46 is provided in the housing 45 and presses one or both of the first and second valve elements 41 and 42 inserted into between the first opening part OP1 and the second opening part OP2 toward the second opening part OP2. The pressing part 46 has an annular shape adapted to the first and second opening parts OP1 and OP2 not to interrupt the flow of gases. In the first embodiment, the pressing part 46 presses both of the first and second valve elements 41 and 42 inserted into between the first opening part OP1 and the second opening part OP2 to block between the chamber 10 and the vacuum pump 60. For example, when the gases are to be caused to flow from the chamber 10 to the exhaust line 70 during etching processing, the pressing part 46 is located away from the first and second valve elements 41 and 42. On the other hand, when the chamber is to be blocked from the vacuum pump 60 to keep a pressure state in the chamber 10, the pressing part 46 is moved by a driver 47 in the direction D1 (downward in FIG. 2) to press the first and second valve elements 41 and 42 inserted into between the first opening part OP1 and the second opening part OP2 toward the second opening part OP2. The first opening part OP1 and the second opening part OP2 are thereby blocked from each other and the chamber 10 is airtightly blocked from the vacuum pump 60. Alternatively, the pressing part 46 can be configured to press either the first valve element 41 or the second valve element 42. For example, when the second valve element 42 can close the second opening part OP2 alone, the pressing part 46 can press only the second valve element 42 out of the first and second valve elements 41 and 42 toward the second opening part OP2 to close the second opening part OP2.

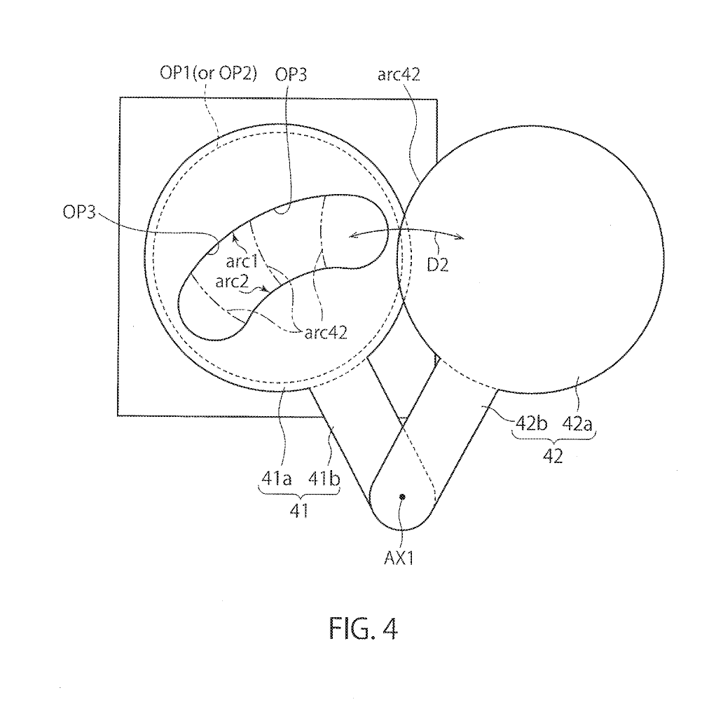

FIG. 3 is a plan view showing an example of configurations of the first and second valve elements 41 and 42. FIG. 4 shows a state where the second valve element 42 is moved with respect to the first valve element 41 overlapped with the first or second opening part OP1 or OP2. The configurations of the first and second valve elements 41 and 42 are explained further with reference to FIGS. 3 and 4. In the first embodiment, the first and second valve elements 41 and 42 are rotatable around the common axis AX1 in a direction D2.

### (First Valve Element 41)

The first valve element 41 includes a first insertion part (body) 41a and a first connection part (arm) 41b.

The first insertion part 41a is a member of a substantially flat-plate shape and the outer edge thereof is larger than the first and second opening parts OP1 and OP2 and is located outside the outer edges of the first and second opening parts OP1 and OP2. Although not particularly limited thereto, a shape of the outer edge of the first insertion part 41a has a substantially similar shape to those (cross-sectional shapes in a direction perpendicular to the direction D1 in FIG. 2) of the first and second opening parts OP1 and OP2. For example, when the shapes of the first and second opening parts OP1 and OP2 are substantially circular as shown in FIG. 3, the shape of the outer edge of the first insertion part 41a is also substantially circular. The entire size of the pressure control valve 40 can be reduced by thus adapting the shape of the first insertion part 41a to the shapes of the first and second opening parts OP1 and OP2. Because the outer edge of the first insertion part 41a is larger than the first and second opening parts OP1 and OP2 and is located outside the outer edges of the first and second opening parts OP1 and OP2, the first insertion part 41a overlaps with the first and second opening parts OP1 and OP2 at least partially when inserted into between the first opening part OP1 and the second opening part OP2. That is, the first valve element 41 can cover a part or the entirety of the first or second opening part OP1 or OP2 in a region other than the third opening part OP3. The first and second opening parts OP1 and OP2 indicate opening portions near the first and second valve elements 41 and 42 and, for example, indicate opening portions just before or just after (just above or just below) the first and second valve elements 41 and 42.

The first connection part 41b is connected between the first shaft SH1 shown in FIG. 2 and the first insertion part 41a and can rotate the first insertion part 41a around the first shaft SH1.

The first insertion part 41a has the third opening part OP3 therein. The opening area of the third opening part OP3 is smaller than those of the first and second opening parts OP1 and OP2. Therefore, when the first valve element 41 overlaps with the first or second opening part OP1 or OP2 and covers the first or second opening part OP1 or OP2 in a region other than the third opening part OP3, the opening area of the first or second opening part OP1 or OP2 can be reduced to the opening area of the third opening part OP3 in a stepwise manner. That is, the gas conductance between the first pipe P1 and the second pipe P2 decreases in a stepwise manner. The conductance is proportional to the opening area in which the gases flow. Therefore, for example, when the opening area of the third opening part OP3 is about 50% of the opening area of the first or second opening part OP1 or OP2, the gas conductance also decreases by about 50% when the first valve element 41 overlaps with the first or second opening part OP1 or OP2. When the first valve element 41 overlaps with the second opening part OP2, a part of the first valve element 41 can be overlapped with the second opening part OP2. In this way, the first valve element 41 can change the gas conductance between the first pipe P1 and the second pipe P2.

A planar shape of the third opening part OP3 is an elliptic shape curved like an arc and has a major axis in the insertion or removal direction (rotation direction) D2 of the second valve element 42 as shown in FIG. 3. Because the first and second valve elements 41 and 42 rotate around the same axis AX1 in the first embodiment, the direction D2 is the same as the insertion or removal direction (rotation direction) of the first valve element 41. However, when the rotation axis of the second valve element 42 is different from that of the first valve element 41, the shape of the third opening part OP3 has a major axis in the rotation direction of the second valve element 42. That is, the shape of the third opening part OP3 has a major axis in the rotation direction D2 around the second shaft SH2 (the axis AX1). Accordingly, when the second valve element 42 is inserted into between the first opening part OP1 and the second opening part OP2 after the first valve element 41 is inserted into between the first opening part OP1 and the second opening part OP2 to be overlapped with the first or second opening part OP1 or OP2, the second valve element 42 can gradually reduce the opening area of the third opening part OP3 little by little. That is, the second valve element 42 can finely adjust the gas conductance between the first pipe P1 and the second pipe P2 while reducing the opening area of the third opening part OP3 little by little. The second valve element 42 can thereby close a part of the third opening part OP3 of the first valve element 41 and finely adjust the pressure in the chamber 10.

For example, the shape of the third opening part OP3 is a shape enclosed by a first arc arc1, a second arc arc2, and two third arcs arc3. The first arc arc1 is an arc having a first radius r1 around the second shaft SH2 (the axis AX1). The second arc arc2 is an arc having a second radius r2 smaller than the first radius r1 around the second shaft SH2 (the axis AX1). The two third arcs arc3 are arcs connecting between the first arc arc1 and the second arc arc2. The distance between the first arc arc1 and the second arc arc2 is not particularly limited as long as it is smaller than the diameter of the first Insertion part 41a.

Because the first arc arc1 and the second arc arc2 are arcs around the axis AX1 of the second valve element 42, the second valve element 42 can move in a direction (D2) substantially parallel to the first and second arcs arc1 and arc2 as shown by dashed lines (arc42) in FIG. 4. Therefore, the pressure control valve 40 can easily regulate (control) the opening area of the third opening part OP3 based on a movement distance or a rotation angle of the second valve element 42.

The third arcs arc3 can have substantially the same diameter as that of the arc arc42 of the outer edge of a second insertion part 42a of the second valve element 42. When the third arcs arc3 have substantially the same diameter as that of the arc arc42 of the outer edge of the second insertion part 42a, one of the third arcs arc3 and the arc arc42 become substantially parallel to each other just before the second valve element 42 entirely closes the third opening part OP3. Accordingly, the opening area of the third opening part OP3 can be easily controlled based on the distance between the third arc arc3 and the arc arc42. In this way, regulation (control) of the gas conductance in the third opening part OP3 using the second valve element 42 is facilitated because the shape of the third opening part OP3 is defined by the first to third arcs arc1 to arc3.

### (Second Valve Element 42)

The second valve element 42 includes the second insertion part (body) 42a and a second connection part (arm) 42b.

The second insertion part 42a is also a member of a substantially flat-plate shape and the outer edge thereof is larger than the first and second opening parts OP1 and OP2 and is located outside the outer edges of the first and second opening parts OP1 and OP2. Although not particularly limited thereto, the shape of the outer edge of the second insertion part 42a has a substantially similar shape to those (the cross-sectional shapes in a direction perpendicular to the direction D1 in FIG. 2) of the first and second opening parts OP1 and OP2. For example, when the shapes of the first and second opening parts OP1 and OP2 are substantially circular, the shape of the outer edge of the second insertion part 42a is also substantially circular. The entire size of the pressure control valve 40 can be reduced by thus adapting the shape of the second insertion part 42a to the shapes of the first and second opening parts OP1 and OP2. Because the outer edge of the second insertion part 42a is larger than the first and second opening parts OP1 and OP2 and is located outside the outer edges of the first and second opening parts OP1 and OP2, the second insertion part 42a overlaps with the first or second opening part OP1 or OP2 when inserted into between the first opening part OP1 and the second opening part OP2.

That is, the second valve element 42 can entirely cover the first or second opening part OP1 or OP2.

While the outer edge of the second insertion part 42a is larger than the first and second opening parts OP1 and OP2 and is located outside the outer edges of the first and second opening parts OP1 and OP2 in the first embodiment, it suffices that the outer edge of the second insertion part 42a is located outside the outer edge of the third opening part OP3 to enable the second valve element 42 to cover the third opening part OP3. Therefore, it is not essential that the outer edge of the second insertion part 42a is located outside the outer edges of the first and second opening parts OP1 and OP2.

The second connection part 42b is connected between the second shaft SH2 shown in FIG. 2 and the second insertion part 42a and can rotate the second insertion part 42a around the second shaft SH2.

The gas conductance between the first pipe P1 and the second pipe P2 is controlled using the first and second valve elements 41 and 42 having the configurations described above in the following manner.

For example, when the first and second valve elements 41 and 42 are removed from between the first opening part OP1 and the second opening part OP2, the first and second opening parts OP1 and OP2 are practically unblocked. Therefore, the opening areas of the first and second opening parts OP1 and OP2 are relatively large and the pressure control valve 40 connects the first pipe P1 and the second pipe P2 with high conductance.

On the other hand, when the first valve element 41 is inserted into between the first opening part OP1 and the second opening part OP2, the first and second opening parts OP1 and OP2 are blocked by the first valve element 41 in a region other than the third opening part OP3. Therefore, the opening areas of the first and second opening parts OP1 and OP2 are reduced to the opening area of the third opening part OP3 and the conductance between the first pipe P1 and the second pipe P2 becomes lower than that in a case where the first valve element 41 is removed from between the first opening part OP1 and the second opening part OP2.

When the first valve element 41 is inserted into between the first opening part OP1 and the second opening part OP2 and then at least a part of the second valve element 42 is further inserted into between the first opening part OP1 and the second opening part OP2, at least a part of the third opening OP3 of the first valve element 41 is blocked correspondingly by the second valve element 42. Therefore, the opening area of the third opening part OP3 is reduced and the conductance between the first pipe P1 and the second pipe P2 is decreased gradually. When the second valve element 42 entirely closes the third opening part OP3, the conductance between the first pipe P1 and the second pipe P2 becomes quite low or becomes almost zero.

Conversely, the conductance between the first pipe P1 and the second pipe P2 can be increased gradually or in a stepwise manner by removing the second valve element 42 or the first valve element 41 from between the first opening part OP1 and the second opening part OP2.

In this way, the pressure control valve 40 can finely regulate the gas conductance between the chamber 10 and the vacuum pump 60 according to a position (an insertion degree) of the first or second valve element 41 or 42 between the first opening part OP1 and the second opening part OP2. As a result, the pressure control valve 40 can finely adjust the pressure in the chamber 10.

As described above, according to the first embodiment, the pressure control valve 40 includes the plural valve elements 41 and 42 and the first valve element 41 has the third opening part OP3. The first valve element 41 can change the opening area of the first or second opening part OP1 or OP2 to the opening area of the third opening part OP3 in a stepwise manner. The second valve element 42 can finely adjust the gas conductance of the third opening part OP3 by closing a part or the entirety of the third opening part OP3 of the first valve element 41. The second valve element 42 can also airtightly block between the first opening part OP1 and the second opening part OP2 by overlapping with and closing the third opening part OP3.

If the pressure control valve 40 includes only a single valve element, the pressure control valve 40 needs to control the gas conductance between the first opening part OP1 and the second opening part OP2 using only the single valve element. In this case, the valve element needs to be larger than the opening area of the first or second opening part OP1 or OP2 to be capable of closing the first or second opening part OP1 or OP2. Furthermore, the valve element directly regulates the opening area of the first or second opening part OP1 or OP2. However, because the opening area of the first or second opening part OP1 or OP2 is relatively large, fine adjustment of the gas conductance between the first pipe P1 and the second pipe P2 is difficult.

In contrast, the pressure control valve 40 according to the first embodiment has the plural valve elements 41 and 42. The first valve element 41 includes the third opening part OP3 having a smaller opening area than those of the first and second opening parts OP1 and OP2. Accordingly, the first valve element 41 first overlaps with the first and second opening parts OP1 and OP2 to change the opening areas of the first and second opening parts OP1 and OP2 to the opening area of the third opening part OP3. Next, the second valve element 42 closes at least a part of the third opening part OP3 to regulate (control) the opening area of the third opening part OP3. In this way, the pressure control valve 40 can change the change rate of the opening area in a stepwise manner or gradually using the first and second valve elements 41 and 42. As a result, the gas conductance between the first pipe P1 and the second pipe P2 can be adjusted finely.

### Second Embodiment

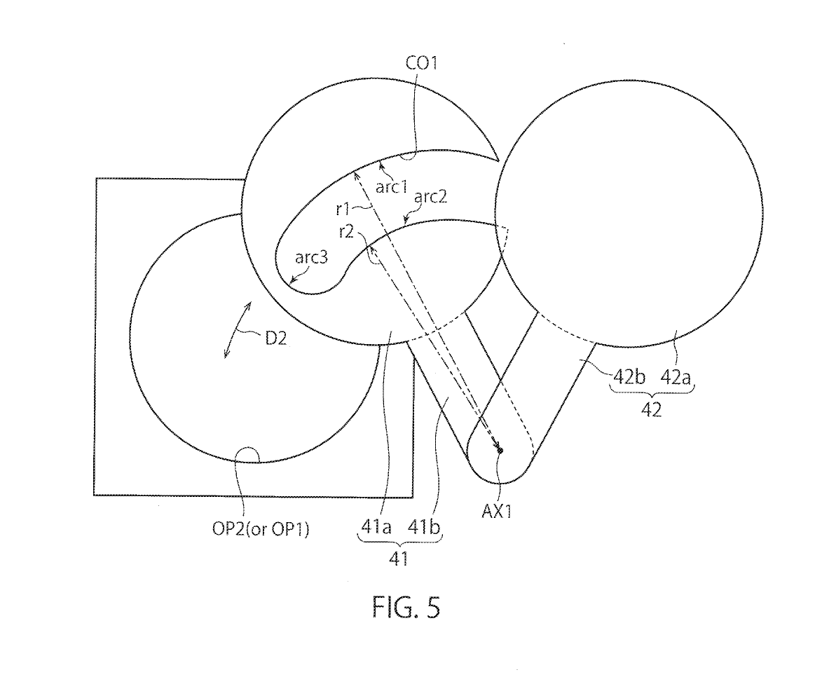

FIG. 5 is a plan view showing an example of a configuration of the pressure control valve 40 according to a second embodiment.

The first valve element 41 in the second embodiment has a cutout CO1 instead of the third opening part OP3. Other configurations of the second embodiment can be identical to corresponding ones of the first embodiment.

For example, the cutout CO1 has a curved substantially U-shape including the first arc arc1, the second arc arc2, and the third arc arc3. Accordingly, when the first valve element 41 is inserted into between the first opening part OP1 and the second opening part OP2, a partial arc of the first or second opening part OP1 or OP2 and the cutout CO1 form the third opening part OP3 smaller than the first and second opening parts OP1 and OP2. The first to third arcs arc1 to arc3 can be identical to those in the first embodiment.

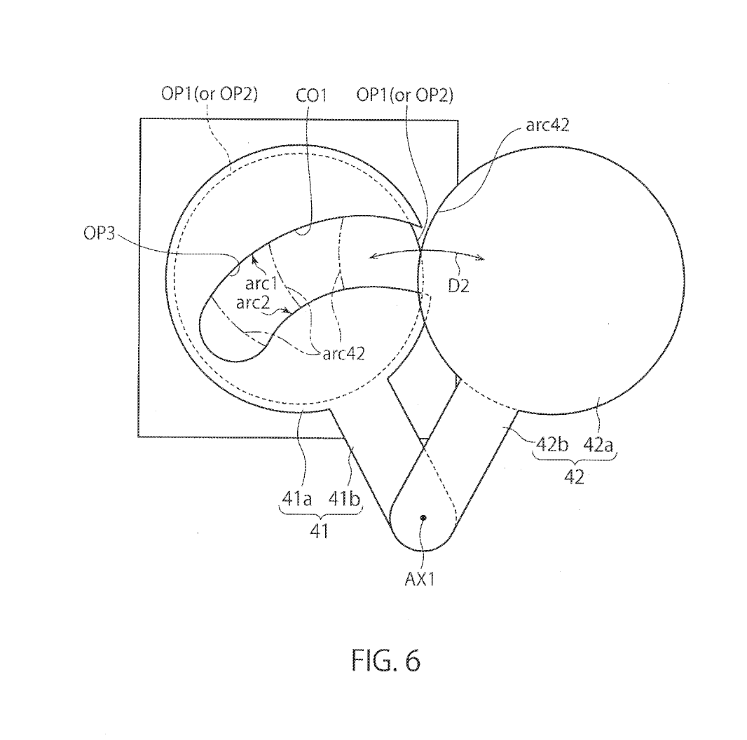

FIG. 6 shows a state where the second valve element 42 is moved with respect to the first valve element 41 overlapped with the first or second opening part OP1 or OP2. As shown in FIG. 6, when the first valve element 41 overlaps with the first or second opening part OP1 or OP2, the cutout CO1 and a partial arc of the first or second opening part OP1 or OP2 form the third opening part OP3. That is, in the second embodiment, the third opening part OP3 Is formed by a partial arc of the first or second opening part OP1 or OP2 not covered due to the cutout CO1 and the cutout CO1.

The second valve element 42 moves in a direction (D2) substantially parallel to the first and second arcs arc1 and arc2. Therefore, the pressure control valve 40 can easily regulate (control) the opening area of the third opening part OP3 based on a movement distance or a rotation angle of the second valve element 42. Accordingly, also when the first valve element 41 has the cutout CO1, an identical effect to that in the first embodiment can be achieved.

The third arc arc3 can have substantially the same diameter as the arc arc42 of the outer edge of the second insertion part 42a of the second valve element 42. Because the third arc arc3 and the arc arc42 thus become substantially parallel to each other just before the second valve element 42 entirely closes the third opening part OP3, the pressure control valve 40 according to the second embodiment can easily regulate (control) the opening area of the third opening part OP3 based on the distance between the third arc arc3 and the second valve element 42 similarly in the first embodiment.

### (Modification)

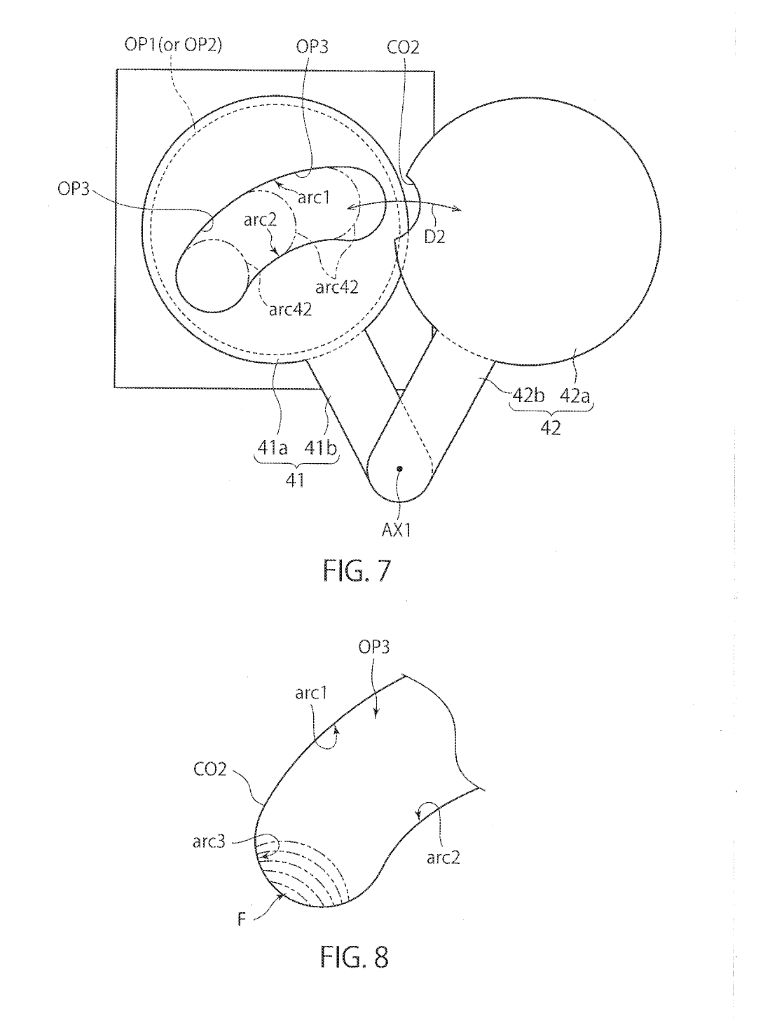

FIG. 7 is a plan view showing an example of a configuration of the pressure control valve 40 according to a modification of the first embodiment. The second valve element 42 in the present modification has a cutout CO2 in a part thereof. Other configurations of the present modification can be identical to corresponding ones of the first embodiment.

The cutout CO2 is provided at an outer edge portion of the second valve element 42 intersecting (overlapping) with the third opening part OP3 when the second valve element 42 is inserted into between the first opening part OP1 and the second opening part OP2. The cutout CO2 has an arc having substantially the same diameter as that of the third arcs arc3 of the third opening part OP3 shown in FIG. 3 and is curved toward the opposite side to the third arcs arc3. It suffices that the width of the cutout CO2 is equal to or larger than the width of the third arcs arc3, that is, the distance between the first arc arc1 and the second arc arc2.

Accordingly, when the second valve element 42 is inserted into between the first opening part OP1 and the second opening part OP2 after the first valve element 41 is inserted into between the first opening part OP1 and the second opening part OP2, the second valve element 42 can reduce the opening area of the third opening part OP3 gradually little by little as shown by dashed lines (arc42) in FIG. 7. Furthermore, as shown in FIG. 8, when the cutout CO2 approaches one of the third arcs arc3 and starts overlapping with the third opening part OP3, the opening area of the third opening part OP3 becomes the area of a fusiform portion F formed by the arc of the cutout CO2 and the other of the third arcs arc3. FIG. 8 is a plan view showing a motion of the cutout CO2 with respect to the third opening part OP3. The area of the fusiform portion F can be adjusted more finely by moving the second valve element 42. That is, provision of the cutout CO2 in the second valve element 42 enables the opening area of the third opening part OP3 to be adjusted more finely and thus the gas conductance between the first pipe P1 and the second pipe P2 can be adjusted more finely. Furthermore, the present modification can achieve other effects of the first embodiment. The present modification can be also applied to the second embodiment.

While certain embodiments have been described, these embodiments have been presented by way of example only, and are not intended to limit the scope of the inventions. Indeed, the novel methods and systems described herein may be embodied in a variety of other forms; furthermore, various omissions, substitutions and changes in the form of the methods and systems described herein may be made without departing from the spirit of the inventions. The accompanying claims and their equivalents are intended to cover such forms or modifications as would fall within the scope and spirit of the inventions.

1. A valve comprising:
a housing including a first opening part connectable to a first pipe and a second opening part connectable to a second pipe, and capable of connecting the first pipe and the second pipe;
a first valve element provided in the housing and capable of being inserted into or removed from between the first opening part and the second opening part, the first valve element including an outer edge located outside an outer edge of the first or second opening part, the first valve element including a third opening part smaller than the first and second opening parts; and
a second valve element provided in the housing and capable of being inserted into or removed from between the first opening part and the second opening part, the second valve element including an outer edge located outside an outer edge of the third opening part, the second valve element being capable of closing at least a part of the third opening part.

2. The valve of claim 1, wherein
the first valve element comprises:
a first insertion part at least partially overlapping with the first or second opening part when inserted into between the first opening part and the second opening part, the first insertion part including the third opening part; and
a first connection part connected between a first shaft provided outside the first opening part and the first insertion part, the first connection part rotating the first insertion part around the first shaft, and
the second valve element comprises:
a second insertion part overlapping with the first or second opening part when inserted into between the first opening part and the second opening part; and
a second connection part connected between a second shaft provided outside the first opening part and the second insertion part, the second connection part rotating the second insertion part around the second shaft.

3. The valve of claim 2, wherein the first shaft and the second shaft are capable of rotating around substantially same axis.

4. The valve of claim 1, wherein a shape of the third opening part has a major axis in a direction of insertion or removal of the second valve element.

5. The valve of claim 2, wherein a shape of the third opening part has a major axis in a direction of rotation around the second shaft.

6. The valve of claim 2, wherein a shape of the third opening part has a first arc having a first radius around the second shaft, a second arc having a second radius smaller than the first radius around the second shaft, and third arcs connecting between the first arc and the second arc.

7. The valve of claim 5, wherein a shape of the third opening part has a first arc having a first radius around the second shaft, a second arc having a second radius smaller than the first radius around the second shaft, and third arcs connecting between the first arc and the second arc.

8. The valve of claim 1, wherein the second valve element is inserted into between the first opening part and the second opening part after the first valve element is inserted into between the first opening part and the second opening part.

9. The valve of claim 7, wherein the second valve element has a cutout at an outer edge portion of the second valve element intersecting with the third opening part.

10. The valve of claim 1, further comprising a pressing part provided in the housing, the pressing part pressing either the first or second valve element or both of the first and second valve elements inserted into between the first opening part and the second opening part toward the first or second opening part.

11. The valve of claim 1, wherein
the first pipe is connected to a chamber, and the second pipe is connected to a vacuum pump, and
the second valve element controls a pressure in the chamber by closing at least a part of the third opening part after the first valve element is inserted into between the first opening part and the second opening part.

12. A valve comprising:
a housing having a first opening part connectable to a first pipe and a second opening part connectable to a second pipe, and capable of connecting the first pipe and the second pipe;
a first valve element provided in the housing and capable of being inserted into or removed from between the first opening part and the second opening part, the first valve element having a cutout, the first or second opening part and the cutout forming a third opening part smaller than the first and second opening parts when the first valve element is inserted into between the first opening part and the second opening part; and
a second valve element provided in the housing and capable of being inserted into or removed from between the first opening part and the second opening part, the second valve element including an outer edge located outside an outer edge of the third opening part, the second valve element being capable of closing at least a part of the third opening part.

13. The valve of claim 12, wherein the first shaft and the second shaft are capable of rotating around substantially same axis.

14. The valve of claim 12, wherein a shape of the cutout has a major axis in a direction of insertion or removal of the second valve element.

15. The valve of claim 13, wherein a shape of the cutout has a major axis in a direction of rotation around the second shaft.

16. The valve of claim 13, wherein a shape of the cutout has a first arc having a first radius around the second shaft, a second arc having a second radius smaller than the first radius around the second shaft, and a third arc connecting between the first arc and the second arc.

17. The valve of claim 15, wherein a shape of the cutout has a first arc having a first radius around the second shaft, a second arc having a second radius smaller than the first radius around the second shaft, and a third arc connecting between the first arc and the second arc.

18. The valve of claim 12, wherein the second valve element is inserted into between the first opening part and the second opening part after the first valve element is inserted into between the first opening part and the second opening part.

19. The valve of claim 18, wherein the second valve element has a cutout at an outer edge portion of the second valve element intersecting with the third opening part.

20. A semiconductor manufacturing equipment comprising:
a chamber;
a vacuum pump reducing a pressure in the chamber;
a first pipe connected to the chamber;
a second pipe connected to the vacuum pump; and
a valve connected between the first pipe and the second pipe, wherein
the valve comprises:
a housing having a first opening part connectable to the first pipe and a second opening part connectable to the second pipe, and capable of connecting the first pipe and the second pipe;
a first valve element provided in the housing and capable of being inserted into or removed from between the first opening part and the second opening part, the first valve element including an outer edge located outside an outer edge of the first or second opening part, the first valve element including a third opening part smaller than the first and second opening parts or including a cutout forming a third opening part smaller than the first and second opening parts when inserted into between the first opening part and the second opening part; and
a second valve element provided in the housing and capable of being inserted into or removed from between the first opening part and the second opening part, the second valve element including an outer edge located outside an outer edge of the third opening part, the second valve element being capable of closing at least a part of the third opening part.
